(19) United States
(12) Patent Application Publication
(10) Pub. No.: US 2010/0289142 A1
(43) Pub. Date: Nov. 18, 2010

(54) INTEGRATED CIRCUIT PACKAGING SYSTEM WITH COIN BONDED INTERCONNECTS AND METHOD OF MANUFACTURE THEREOF

(76) Inventors: Il Kwon Shim, Singapore (SG); Seng Guan Chow, Singapore (SG); Heap Hoe Kuan, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/777,615

(22) Filed: May 11, 2010

Related U.S. Application Data
(60) Provisional application No. 61/178,864, filed on May 15, 2009.

(51) Int. Cl. H01L 23/498; H01L 21/56; H01L 23/28; H01L 21/60

(52) U.S. Cl. 257/738; 438/124; 257/737; 257/E21.511; 257/E21.502; 257/E23.068; 257/E23.116

(57) ABSTRACT

A method of manufacture of an integrated circuit packaging system includes: providing a substrate; attaching an interconnect to the substrate; encapsulating the interconnect with an encapsulation leaving a portion of the interconnect not encapsulated; attaching a joint to the interconnect and simultaneously creating a coined-surface of the interconnect contacting the joint; and attaching an integrated circuit to the substrate.

### CROSS-REFERENCE TO RELATED APPLICATION(S)

This application claims the benefit of U.S. Provisional Patent Application Ser. No. 61/178,864 filed May 15, 2009, and the subject matter thereof is incorporated herein by reference thereto.

### TECHNICAL FIELD

The present invention relates generally to an integrated circuit packaging system and more particularly to a system for utilizing coin bonded interconnects in an integrated circuit packaging system.

### BACKGROUND

The rapidly growing market for portable electronics devices, e.g. cellular phones, laptop computers, and PDAs, is an integral facet of modern life. The multitude of portable devices represents one of the largest potential market opportunities for next generation packaging. These devices have unique attributes that have significant impacts on manufacturing integration, in that they must be generally small, lightweight, and rich in functionality and they must be produced in high volumes at relatively low cost.

As an extension of the semiconductor industry, the electronics packaging industry has witnessed ever-increasing commercial competitive pressures, along with growing consumer expectations and the diminishing opportunities for meaningful product differentiation in the marketplace.

Packaging, materials engineering, and development are at the very core of these next generation electronics insertion strategies outlined in road maps for development of next generation products. Future electronic systems may be more intelligent, have higher density, use less power, operate at higher speed, and may include mixed technology devices and assembly structures at lower cost than today.

Current packaging suppliers are struggling to accommodate the high-speed computer devices that are projected to exceed one TeraHertz (THz) in the near future. The current technologies, materials, equipment, and structures offer challenges to the basic assembly of these new devices while still not adequately addressing cooling and reliability concerns.

The envelope of technical capability of next level interconnect assemblies are not yet known, and no clear cost effective technology has yet been identified. Beyond the performance requirements of next generation devices, the industry now demands that cost be a primary product differentiator in an attempt to meet profit goals.

As a result, the road maps are driving electronics packaging to precision, ultra miniature form factors, which require automation in order to achieve acceptable yield. These challenges demand not only automation of manufacturing, but also the automation of data flow and information to the production manager and customer.

There have been many approaches to addressing the advanced packaging requirements of microprocessors and portable electronics with successive generations of semiconductors. Many industry road maps have identified significant gaps between the current semiconductor capability and the available supporting electronic packaging technologies. The limitations and issues with current technologies include increasing clock rates, EMI radiation, thermal loads, second level assembly reliability stresses and cost.

As these package systems evolve to incorporate more components with varied environmental needs, the pressure to push the technological envelope becomes increasingly challenging. More significantly, with the ever-increasing complexity, the potential risk of error increases greatly during manufacture.

In view of the ever-increasing commercial competitive pressures, along with growing consumer expectations and the diminishing opportunities for meaningful product differentiation in the marketplace, it is critical that answers be found for these problems. Additionally, the need to reduce costs, reduce production time, improve efficiencies and performance, and meet competitive pressures, adds an even greater urgency to the critical necessity for finding answers to these problems.

Thus, a need remains for smaller footprints and more robust packages and methods for manufacture. Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a substrate; attaching an interconnect to the substrate; encapsulating the interconnect with an encapsulation leaving a portion of the interconnect not encapsulated; attaching a joint to the interconnect and simultaneously creating a coined-surface of the interconnect contacting the joint; and attaching an integrated circuit to the substrate.

The present invention provides an integrated circuit packaging system including: a substrate; an interconnect attached to the substrate; an encapsulation that encapsulates the interconnect; a joint attached to the interconnect with a coined-surface of the interconnect; and an integrated circuit attached to the substrate.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system in an embodiment of the present invention.

FIG. 2A is the integrated circuit packaging system of FIG. 1 after an encapsulation phase of manufacture.

FIG. 2B is the integrated circuit packaging system of FIG. 2A during a coining phase of manufacture.

FIG. 2C is the integrated circuit packaging system of FIG. 2A after an under-filling phase of manufacture.

FIG. 2D is the integrated circuit packaging system of FIG. 2A after an external interconnect attach phase of manufacture.

FIG. 3 is a cross-sectional view of an integrated circuit packaging system in an embodiment of the present invention.

FIG. 4 is a cross-sectional view of an integrated circuit packaging system in an embodiment of the present invention.

FIG. 5 is a flow chart of a method of manufacture of the integrated circuit packaging system of FIG. 1.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

In addition, where multiple embodiments are disclosed and described having some features in common, for clarity and ease of illustration, description, and comprehension thereof, similar and like features from one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements without having any intervening material.

The term “processing” as used herein includes deposition of material or photoresist, patterning, exposure, development, etching, cleaning, and/or removal of the material or photoresist as required in forming a described structure.

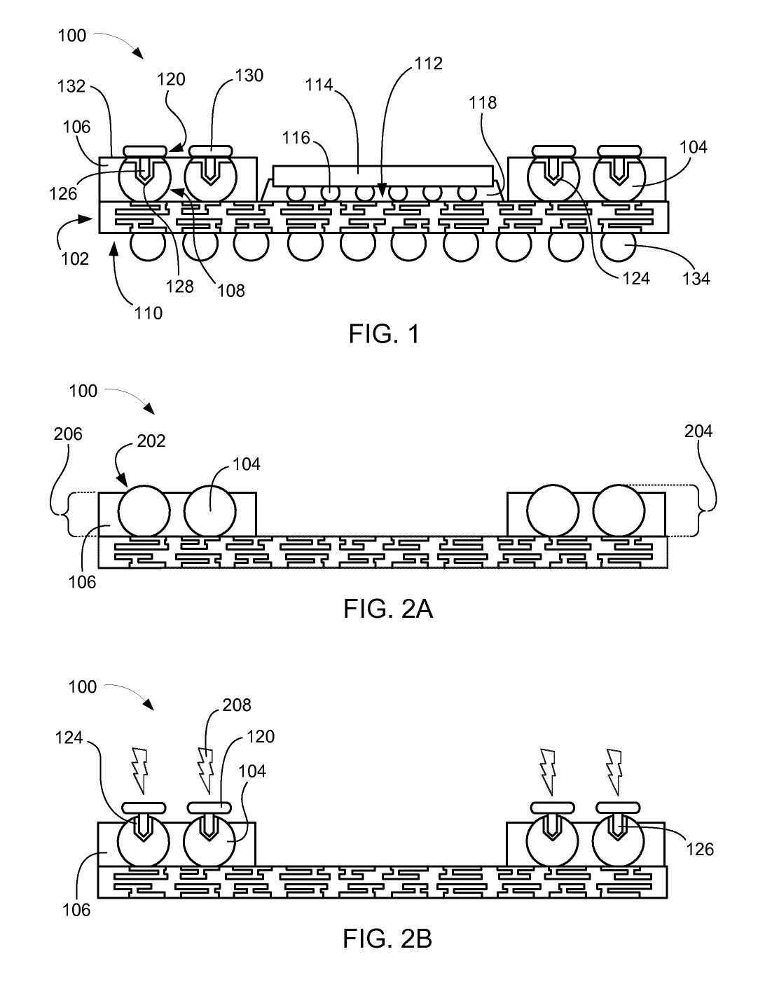

Referring now to FIG. 1, therein is shown a cross-sectional view of an integrated circuit packaging system 100 in an embodiment of the present invention. The integrated circuit packaging system 100 is shown having a substrate 102 such as a laminated plastic or ceramic substrate.

Above the substrate 102, interconnects 104 are mounted. The interconnects 104 are made of conductive materials and may be solid solder balls. The interconnects 104 may also be copper-cored or polymer-cored solder balls. Finally the interconnects 104 may also be copper, gold, or silver studs, pillars, stacks of solder balls, or combinations thereof.

The interconnects 104 are encapsulated by an encapsulation 106 such as film assisted molding. The encapsulation 106 covers sides 108 of the interconnects 104 and reinforces the interconnects 104 above the substrate 102. The encapsulation 106 has been unexpectedly discovered to greatly increase adhesion and electrical conductivity between the interconnect 104 and the substrate 102.

The encapsulation 106 is formed around a perimeter 110 of the substrate 102 leaving a center portion 112 of the substrate 102 exposed from, and not encapsulated by, the encapsulation 106. Mounted on the center portion 112 of the substrate 102 and between the encapsulation 106 is an integrated circuit 114 such as a flip chip. The integrated circuit 114 is electrically connected to the substrate 102 with circuit-interconnects 116 such as solder balls.

The circuit-interconnects 116 may be reinforced by an under-fill 118 between the integrated circuit 114 and the substrate 102 and that surrounds the circuit-interconnects 116. Above the interconnects 104, joints 120 such as copper or metallic joints are attached. The joints 120 are attached to the interconnects 104 by coining the interconnects 104. A joint is defined herein as an electrically conductive structure.

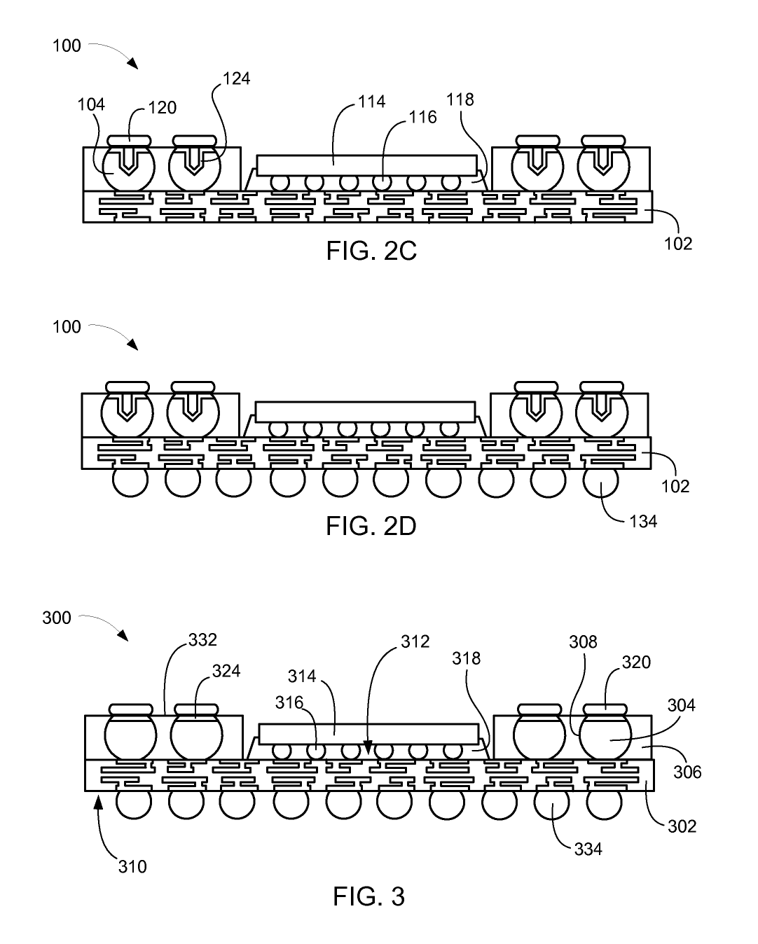

Coin, coined, or the process of coining is defined herein as subjecting a work piece or the result of subjecting a work piece to sufficient stress to induce a plastic flow along the surface of the work piece. This is shown in FIG. 2B and produces unexpected beneficial results when applied to the manufacturing of the interconnects 104. Sufficient stress may include thermal stress, mechanical stress, or a combination of the two.

One benefit of coining the interconnects 104 is that the plastic flow induced in the surface of the interconnects 104 creates a coined-surface 124 having a very fine grain structure providing a work-hardened surface while the deeper material in the interconnects 104 retains its toughness and ductility.

Another benefit of coining the interconnect 104 is that the coined-surface 124 of the interconnect 104 adheres substantially better to the joint 120. This adhesion comes from the fact that as the stress of coining induces plastic flow along the coined-surface 124 of the interconnect 104 the plastic flow molds correctly and strictly to the surface of the joint 120 that is in contact with the interconnect 104.

The joint 120 is shown to have a t-shape with a vertical portion 126 submerged into the interconnect 104. The vertical portion 126 of the joint 120 is further shown having a pointy tip 128, which can help during the coining process.

The joint 120 further has a horizontal portion 130 that is shown attached to the coined-surface 124 of the interconnect 104. The encapsulation 106 is shown having a top surface 132 that is coplanar with the coined-surface 124 of the interconnect 104 that is in contact with the horizontal portion 130 of the joint 120. Mounted below the substrate 102 are external interconnects 134 such as solder balls.

Referring now to FIG. 2A, therein is shown the integrated circuit packaging system 100 of FIG. 1 after an encapsulation phase of manufacture. The integrated circuit packaging system 100 is shown having the encapsulation 106 formed around the interconnects 104 leaving a portion 202 of the interconnects 104 exposed. The interconnects 104 are shown having a height 204 that includes the portion 202 of the interconnects 104 that are exposed from the encapsulation 106, while the encapsulation 106 is shown having a thickness 206.

It has been discovered that the thickness 206 of the encapsulation 106 should range from 30% to 90% of the height 204 of the interconnects 104 and preferably should be 40% to 70% of the height 204 of the interconnects 104. This leaves an adequate portion 202 of the interconnect 104 unencumbered during the coining process of FIG. 2B.

Referring now to FIG. 2B, therein is shown the integrated circuit packaging system 100 of FIG. 2A during a coining phase of manufacture. The integrated circuit packaging system 100 is shown having the joints 120 bonded to the interconnects 104 with enough stress 208 to create the coined-surface 124 to forcefully bond the joint 120 to the interconnect 104.

It is also possible during this phase of manufacture for the surface of the joint 120 that is in contact with the interconnect 104 to achieve a plastic flow. This will result in a coined-surface along the joint 120 in the portions that contact the interconnect 104. Having a coined-surface in the joint may depend on the relative materials used in the interconnect 104 and the joint 120.

The metallurgical process of coining is well within the scope of one having ordinary skill in the art. For example a copper joint and a copper interconnect with sufficient stress would produce a coined-surface on both the joint 120 and the interconnect 104. Inducing a coined-surface on the joint 120 as well as the interconnect 104 may further bond these elements together creating further beneficial characteristics.

It has further been discovered that during the coining process the vertical portions 126 of the joints 120 are forced into the interconnects 104 and the material comprising the interconnects 104 are displaced by the vertical portions 126 of the joints. This creates greater pressure between the interconnects 104 and the encapsulation 106 ensuring a reinforced and rock solid pressure bond between the encapsulation 106 and the interconnects 104.

Referring now to FIG. 2C, therein is shown the integrated circuit packaging system 100 of FIG. 2A after an under-filling phase of manufacture. The integrated circuit packaging system 100 is shown having the integrated circuit 114 mounted above the substrate 102 and connected with the circuit-interconnects 116. The integrated circuit 114 is further shown as attached to the substrate 102 between the encapsulation 106 which surrounds the integrated circuit 114 and surrounds the center portion 112 of the substrate 102 before the integrated circuit 114 is mounted thereto. The under-fill 118 is shown surrounding the circuit-interconnects 116 and filling between the integrated circuit 114 and the substrate 102.

The joints 120 are also depicted as fully secured to the interconnects 104 and cemented with the coined-surface 124 of the interconnects 104.

Referring now to FIG. 2D, therein is shown the integrated circuit packaging system 100 of FIG. 2A after an external interconnect attach phase of manufacture. The integrated circuit packaging system 100 is shown having the external interconnects 134 attached to the bottom of the substrate 102.

Referring now to FIG. 3, therein is shown a cross-sectional view of an integrated circuit packaging system 300 in an embodiment of the present invention. The integrated circuit packaging system 300 is shown having a substrate 302 such as a laminated plastic or ceramic substrate.

Above the substrate 302, interconnects 304 are mounted. The interconnects 304 may be solid solder balls. The interconnects 304 may also be copper-cored or polymer-cored solder balls. Finally the interconnects 304 may also be copper pillars or gold or silver studs.

The interconnects 304 are encapsulated by an encapsulation 306 such as film assisted molding. The encapsulation 306 covers sides 308 of the interconnects 304 and reinforces the interconnects 304 above the substrate 302.

The encapsulation 306 is formed around a perimeter 310 of the substrate 302 leaving a center portion 312 of the substrate 302 exposed from, and not encapsulated by, the encapsulation 306. Mounted on the center portion 312 of the substrate 302 and between the encapsulation 306 is an integrated circuit 314 such as a flip chip. The integrated circuit 314 is electrically connected to the substrate 302 with circuit-interconnects 316 such as solder balls.

The circuit-interconnects 316 may be reinforced by an under-fill 318 between the integrated circuit 314 and the substrate 302 and that surrounds the circuit-interconnects 316. Above the interconnects 304, joints 320 such as copper or metallic joints are attached. The joints 320 are attached to the interconnects 304 by coining the interconnects 304 (as shown in FIG. 2B).

Attaching the joints 320 by coining the interconnect 304 creates a coined-surface 324 of the interconnect 304 that adheres substantially better to the joint 320. This adhesion comes from the fact that as the stress of coining induces plastic flow along the coined-surface 324 of the interconnect 304 the plastic flow molds correctly and strictly to the surface of the joint 320 that is in contact with the interconnect 304.

The joint 320 is shown to be flat shaped that is attached to the coined-surface 324 of the interconnect 304. The encapsulation 306 is shown having a top surface 332 that is coplanar with the coined-surface 324 of the interconnect 304 that is in contact with the joint 320. Mounted below the substrate 302 are external interconnects 334 such as solder balls.

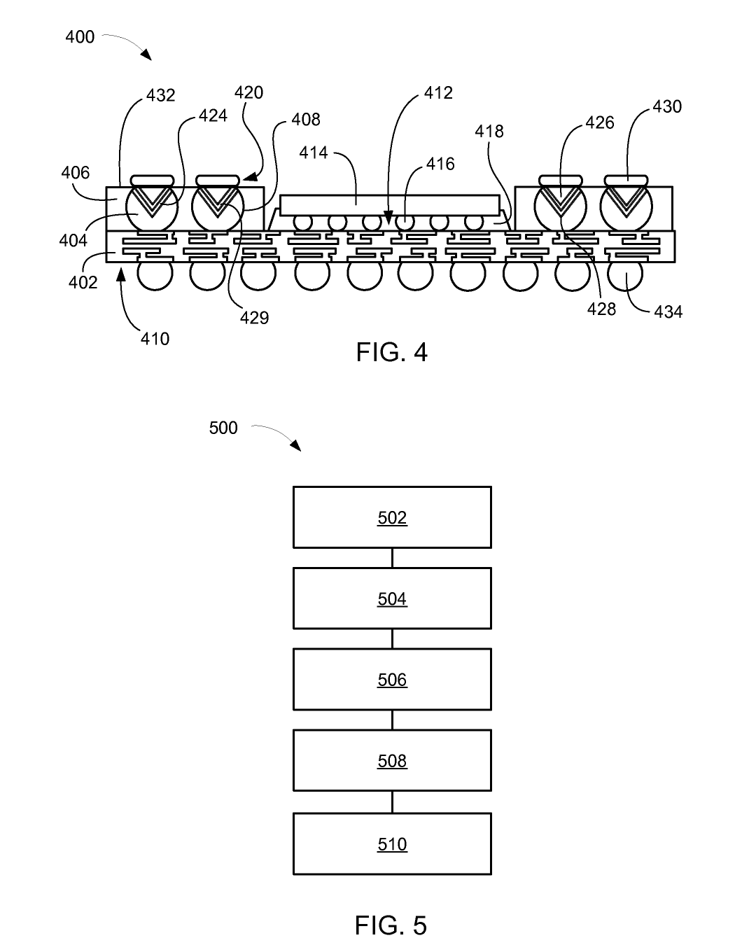

Referring now to FIG. 4, therein is shown a cross-sectional view of an integrated circuit packaging system 400 in an embodiment of the present invention. The integrated circuit packaging system 400 is shown having a substrate 402 such as a laminated plastic or ceramic substrate.

Above the substrate 402, interconnects 404 are mounted. The interconnects 404 may be solid solder balls. The interconnects 404 may also be copper-cored or polymer-cored solder balls. Finally the interconnects 404 may also be copper pillars or gold or silver studs.

The interconnects 404 are encapsulated by an encapsulation 406 such as film assisted molding. The encapsulation 406 covers sides 408 of the interconnects 404 and reinforces the interconnects 404 above the substrate 402.

The encapsulation 406 is formed around a perimeter 410 of the substrate 402 leaving a center portion 412 of the substrate 402 exposed from, and not encapsulated by, the encapsulation 406. Mounted on the center portion 412 of the substrate 402 and between the encapsulation 406 is an integrated circuit 414 such as a flip chip. The integrated circuit 414 is electrically connected to the substrate 402 with circuit-interconnects 416 such as solder balls.

The circuit-interconnects 416 may be reinforced by an under-fill 418 between the integrated circuit 414 and the substrate 402 and that surrounds the circuit-interconnects 416. Above the interconnects 404, joints 420 such as copper or metallic joints are attached. The joints 420 are attached to the interconnects 404 by coining the interconnects 404.

Coining the interconnects 404 requires inducing a plastic flow in the surface of the interconnects 404 to form a coined-surface 424 having a very fine grain structure providing a work-hardened surface while the deeper material in the interconnects 404 retains its toughness and ductility.

The coined-surface 424 of the interconnect 404 adheres substantially better to the joint 420. This adhesion comes from the fact that as the stress of coining induces plastic flow along the coined-surface 424 of the interconnect 404 the plastic flow molds correctly and strictly to the surface of the joint 420 that is in contact with the interconnect 404.

The joint 420 is shown to have a diamond-shape with a pavilion portion 426 submerged into the interconnect 404. The pavilion portion 426 of the joint 420 is further shown having a pointy tip 428, which can help during the coining process.

The pavilion portion 426 of the joint 420 is further shown to have a coined-surface 429 created from the pavilion portion 426 of the joint 420. The coined-surface 429 of the joint 420 is in direct contact with the coined-surface 424 of the interconnect 404.

The joint 420 further has a horizontal portion 430 that is not in contact with the coined-surface 424 of the interconnect 404, instead the coined-surface 424 of the interconnect 404 is shown only contacting the pavilion portion 426 of the joint 420. The encapsulation 406 is shown having a top surface 432 that is coplanar with an edge of the horizontal portion 430 of the joint 420. Mounted below the substrate 402 are external interconnects 434 such as solder balls.

Referring now to FIG. 5, therein is shown a flow chart of a method 500 of manufacture of the integrated circuit packaging system 100 of FIG. 1. The method 500 includes providing a substrate in a block 502; attaching an interconnect to the substrate in a block 504; encapsulating the interconnect with an encapsulation leaving a portion of the interconnect not encapsulated in a block 506; attaching a joint to the interconnect and simultaneously creating a coined-surface of the interconnect contacting the joint in a block 508; and attaching an integrated circuit to the substrate in a block 510.

Thus, it has been discovered that the coined-interconnect of the present invention furnishes important and heretofore unknown and unavailable solutions, capabilities, and functional aspects for integrated circuit packaging system configurations. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacturing an integrated circuit packaging system comprising:
providing a substrate;
attaching an interconnect to the substrate;
encapsulating the interconnect with an encapsulation leaving a portion of the interconnect not encapsulated;
attaching a joint to the interconnect and simultaneously creating a coined-surface of the interconnect contacting the joint; and
attaching an integrated circuit to the substrate.

2. The method as claimed in claim 1 wherein:
attaching the joint includes displacing material of the interconnect to laterally press against the encapsulation.

3. The method as claimed in claim 1 wherein:
attaching the joint creating the coined-surface of the interconnect includes creating a first coined-surface of the interconnect; and
further comprising:
forming a second coined-surface of the joint when mounting the joint to the interconnect, and the second coined-surface is in direct contact with the first coined-surface of the interconnect.

4. The method as claimed in claim 1 wherein:
attaching the joint includes attaching a t-shaped joint, a flat-shaped joint, a diamond-shaped joint, or a combination thereof.

5. The method as claimed in claim 1 wherein:
attaching the joint creating the coined-surface of the interconnect includes creating part of the coined-surface in direct contact with a horizontal portion of the joint, coplanar with a top surface of the encapsulation.

6. A method of manufacture of an integrated circuit packaging system comprising:
providing a substrate having a perimeter and a center portion;
attaching an interconnect to the substrate;
encapsulating the interconnect with an encapsulation leaving a portion of the interconnect not encapsulated;
attaching a joint to the interconnect and simultaneously creating a coined-surface of the interconnect contacting the joint; and
attaching an integrated circuit to the center portion of the substrate.

7. The method as claimed in claim 6 wherein:
encapsulating includes leaving the center-portion of the substrate exposed from the encapsulation.

8. The method as claimed in claim 6 wherein:
attaching the integrated circuit includes attaching a flip chip electrically connected to the substrate by solder balls; and
further comprising:
underfilling between the flip chip and the substrate with an under-fill.

9. The method as claimed in claim 6 wherein:
encapsulating the interconnect leaving the portion of the interconnect exposed from the encapsulation includes encapsulating 40 to 70 percent of the height of the interconnect.

10. The method as claimed in claim 6 wherein:
attaching the joint includes attaching the joint having a pointy tip submerged in the interconnect.

11. The method as claimed in claim 6 wherein:
attaching the interconnect includes forming the interconnect of copper, gold, or silver studs, pillars, stacks of solder balls, or combinations thereof.

12. An integrated circuit packaging system comprising:
a substrate;
an interconnect attached to the substrate;
an encapsulation that encapsulates the interconnect;
a joint attached to the interconnect with a coined-surface of the interconnect; and
an integrated circuit attached to the substrate.

13. The system as claimed in claim 12 wherein:
the joint displaces material of the interconnect to laterally press against the encapsulation.

14. The system as claimed in claim 12 wherein:
the coined-surface of the interconnect is a first coined-surface of the interconnect; and
further comprising:
a second coined-surface of the joint in direct contact with the first coined-surface of the interconnect.

15. The system as claimed in claim 12 wherein:
the joint is a t-shaped joint, a flat-shaped joint, a diamond-shaped joint, or a combination thereof.

16. The system as claimed in claim 12 wherein:
the coined-surface of the interconnect has part of the coined-surface in direct contact with a horizontal portion of the joint, coplanar with a top surface of the encapsulation.

17. The system as claimed in claim 12 further comprising:
a perimeter and a center portion of the substrate; and
wherein:
the integrated circuit is attached to the center portion of the substrate.

18. The system as claimed in claim 17 wherein:
the center-portion of the substrate is exposed from the encapsulation.

19. The system as claimed in claim 17 wherein:
the integrated circuit is a flip chip electrically connected to the substrate with solder balls; and
further comprising:
an under-fill that fills between the flip chip and the substrate.

20. The system as claimed in claim 17 wherein:
the coined-surface of the interconnect is in direct contact only with a pavilion poriton of the joint.

21. The system as claimed in claim 17 wherein:
the joint has a pointy tip submerged in the interconnect.

22. The system as claimed in claim 17 wherein:
the interconnect is formed of copper, gold, or silver studs, pillars, stacks of solder balls, or combinations thereof.
